(19) United States
(12) Patent Application Publication
(10) Pub. No.: US 2021/0091121 A1
(43) Pub. Date: Mar. 25, 2021

(54) ARRAY SUBSTRATE, METHOD OF MANUFACTURING SAME, AND DISPLAY PANEL

(71) Applicant: Wuhan China Star Optoelectronics Technology Co., Ltd., Wuhan, Hubei (CN)

(72) Inventor: Xiaohui NIE, Wuhan (CN)

(73) Assignee: Wuhan China Star Optoelectronics Technology Co., Ltd., Wuhan, Hubei (CN)

(21) Appl. No.: 16/632,393

(22) PCT Filed: Nov. 6, 2019
(86) PCT No.: PCT/CN2019/115879

§ 371 Date: Jan. 20, 2020

(30) Foreign Application Priority Data
Sep. 19, 2019 (CN) 2019108855526.5

(51) Int. Cl. H01L 27/12; H01L 21/66

(52) U.S. Cl. CPC H01L 27/1244; H01L 27/1259; H01L 22/34

(57) ABSTRACT

An array substrate, a method of manufacturing the same, and a display panel are provided. The array substrate includes a base. The base is provided with a non-display region. A thin film transistor layer and a first pixel electrode layer is disposed on the base. The thin film transistor layer includes an interlayer dielectric layer. The interlayer dielectric layer is provided with a first via hole. A detecting device is disposed in the non-display region. The detecting device includes a first source/drain layer disposed in the first via hole, and a second pixel electrode layer connected to the first pixel electrode layer by a trace. The array substrate of the invention enhances a reliability of the detecting device.

### FIELD

The present disclosure relates to display technologies, and more particularly, to an array substrate, a method of manufacturing the same, and a display panel.

### BACKGROUND

A contact impedance between a drain electrode and a pixel electrode of a display panel determines power consumption of a driving circuit and a response speed of charge and discharge of a pixel. The contact impedance between a drain electrode and a pixel electrode need to be measured after providing the pixel of the display panel. Because there exist many layers in a display region of the panel, measuring the contact impedance between a drain electrode and a pixel electrode directly will destroy the layers of the display region. Generally, a detecting device is provided in a non-display region of the panel to measure the contact impedance between a drain electrode and a pixel electrode. The detecting device includes a thin film transistor and a pixel electrode. The pixel electrode is connected to the pixel electrode in the display region by a trace to detect contact impedance between a drain electrode and a pixel electrode.

However, layers of a detecting region of the detecting device is greater than layers of a wiring resistance region, so a difference of height is existed between a trace on the detecting region and a trace on the display region. The trace disposed on a place with height differences is easily broken to cause device failure.

### SUMMARY

In view of the above, the present disclosure provides an array substrate, a method of manufacturing the same, and a display panel to improve a structure of the array substrate to reduce a height difference between a detecting device and a interlayer dielectric layer to prevent from breaking of trace between an interface of the detecting device and the interlayer dielectric layer to promote a reliability of the detecting device.

In order to achieve above-mentioned object of the present disclosure, one embodiment of the disclosure provides an array substrate including a base. The base is provided with a display region and a non-display region. A thin film transistor layer and a first pixel electrode layer are disposed in sequence on the base. The thin film transistor layer includes a thin film transistor disposed in the display region and an interlayer dielectric layer disposed in the non-display region. The first pixel electrode layer is connected to the thin film transistor layer. The interlayer dielectric layer is provided with a first via hole corresponding to the non-display region of the base. A detecting device disposed in the non-display region of the base. The detecting device includes:

a first gate metallic layer deposited on the base corresponding to the first via hole;

a first source/drain layer deposited on the first gate metallic layer, wherein the first source/drain layer is disposed in the first via hole; and

a second pixel electrode layer deposited on the first source/drain layer, wherein the second pixel electrode layer is connected to the first pixel electrode layer by a trace.

In one embodiment of the disclosure, the array substrate further includes a planarization layer disposed between the thin film transistor layer and the first pixel electrode layer. The planarization layer is provided with a second via hole in the non-display region of the base to define a testing region. The first via hole is disposed in the testing region.

In one embodiment of the array substrate of the disclosure, the trace is deposited on the planarization layer and the interlayer dielectric layer.

In one embodiment of the array substrate of the disclosure, an area of the first via hole is greater than or equal to an area of the first gate metallic layer.

In one embodiment of the array substrate of the disclosure, an area of the first via hole is greater than an area of the first gate metallic layer, and the first source/drain layer is totally deposited within the first via hole.

In one embodiment of the array substrate of the disclosure, a height of an upper surface of the first gate metallic layer is less than a height of the interlayer dielectric layer.

In one embodiment of the array substrate of the disclosure, a height of an upper surface of the first source/drain layer is equal to a height of an upper surface of the interlayer dielectric layer.

Furthermore, another embodiment of the disclosure provides a method of manufacturing an array substrate, including steps of:

providing a base, wherein the base is provided with a display region and a non-display region;

providing a thin film transistor layer, a first gate metallic layer and a first source/drain layer on the base, wherein the thin film transistor layer includes a thin film transistor disposed in the display region and an interlayer dielectric layer disposed in the non-display region, the interlayer dielectric layer is provided with a first via hole corresponding to the non-display region of the base, the first gate metallic layer and the first source/drain layer are disposed at the non-display region, the first gate metallic layer is disposed corresponding to the first via hole, and the first source/drain layer is disposed in the first via hole and contacted with the gate metallic layer; and

providing a first pixel electrode layer, a second pixel electrode layer, and a trace on the thin film transistor layer, wherein the first pixel electrode layer is connected to the thin film transistor layer, the second pixel electrode layer is disposed on the first source/drain layer and is connected to the first pixel electrode layer by the trace.

In one embodiment of the disclosure, the method of manufacturing the array substrate further includes steps before the step of providing the first pixel electrode layer, the second pixel electrode layer, and the trace on the thin film transistor layer, wherein the steps include:

providing a planarization layer on the thin film transistor layer; and

providing a second via hole on the planarization layer corresponding to the non-display region to define a testing region, wherein the first via hole is disposed in the testing region, the first pixel electrode layer is disposed on the planarization layer, the second pixel electrode layer is disposed on the first source/drain layer, and the trace is disposed on the planarization layer and the interlayer dielectric layer.

In one embodiment of the method of manufacturing the array substrate of the disclosure, a material of the trace includes indium gallium zinc material.

In one embodiment of the method of manufacturing the array substrate of the disclosure, the step of providing a thin film transistor layer, a first gate metallic layer and a first source/drain layer on the base further includes steps of:

providing a first gate layer and a second gate layer on the base;

providing a first source/drain layer on the first gate layer; and

providing the thin film transistor on the second gate layer.

In one embodiment of the method of manufacturing the array substrate of the disclosure, the step of providing the first gate layer and the second gate layer on the base includes steps of:

coating a layer of gate material on a region on the non-display region of the base corresponding to the first via hole and on the display region of a display panel;

providing a patterned mask layer on the gate material layer; and

shrinking the patterned mask layer by wet etching, and removing part of the gate material layer under a covering of the patterned mask layer to form a first gate metallic layer and a second gate metallic layer respectively.

In one embodiment of the method of manufacturing the array substrate of the disclosure, a height of an upper surface of the first gate metallic layer is less than a height of the interlayer dielectric layer.

In one embodiment of the method of manufacturing the array substrate of the disclosure, a height of an upper surface of the first source/drain layer is equal to a height of an upper surface of the interlayer dielectric layer

Furthermore, another embodiment of the disclosure provides a display panel, including an array substrate. The array substrate includes a base. The base is provided with a display region and a non-display region. A thin film transistor layer and a first pixel electrode layer are disposed in sequence on the base. The thin film transistor layer includes a thin film transistor disposed in the display region and an interlayer dielectric layer disposed in the non-display region. The first pixel electrode layer is connected to the thin film transistor layer. The interlayer dielectric layer is provided with a first via hole corresponding to the non-display region of the base. A detecting device is disposed in the non-display region of the base. The detecting device includes:

a first gate metallic layer deposited on the base corresponding to the first via hole;

a first source/drain layer deposited on the first gate metallic layer, wherein the first source/drain layer is disposed in the first via hole; and

a second pixel electrode layer deposited on the first source/drain layer, wherein the second pixel electrode layer is connected to the first pixel electrode layer by a trace.

In one embodiment of the display panel of the disclosure, the array substrate further includes a planarization layer disposed between the thin film transistor layer and the first pixel electrode layer. The planarization layer is provided with a second via hole in the non-display region of the base to define a testing region. The first via hole is disposed in the testing region.

In one embodiment of the display panel of the disclosure, the trace is deposited on the planarization layer and the interlayer dielectric layer.

In one embodiment of the display panel of the disclosure, an area of the first via hole is greater than or equal to an area of the first gate metallic layer.

In one embodiment of the display panel of the disclosure, a height of an upper surface of the first gate metallic layer is less than a height of the interlayer dielectric layer.

In one embodiment of the display panel of the disclosure, a height of an upper surface of the first source/drain layer is equal to a height of an upper surface of the interlayer dielectric layer.

The array substrate of the disclosure provides the interlayer dielectric layer with a via hole and deposits the first source/drain layer totally within the first via hole to reduce a height difference between the first source/drain layer and the interlayer dielectric layer of the array substrate to prevent from breaking of trace between an interface of the first source/drain layer and the interlayer dielectric layer to promote a reliability of the detecting device.

### BRIEF DESCRIPTION OF DRAWINGS

FIG. 1 is a schematic cross-sectional view of a structure of an array substrate according to an embodiment of the present disclosure.

FIG. 2 is a schematic top view of a structure of an array substrate according to another embodiment of the present disclosure.

FIG. 3 is a schematic flowchart of a method of manufacturing an array substrate according to an embodiment of the present disclosure.

### DETAILED DESCRIPTION

The following description of the embodiments is provided by reference to the drawings and illustrates the specific embodiments of the present disclosure. Directional terms mentioned in the present disclosure, such as “up,” “down,” “top,” “bottom,” “forward,” “backward,” “left,” “right,” “inside,” “outside,” “side,” “peripheral,” “central,” “horizontal,” “peripheral,” “vertical,” “longitudinal,” “axial,” “radial,” “uppermost” or “lowermost,” etc., are merely indicated the direction of the drawings. Therefore, the directional terms are used for illustrating and understanding of the application rather than limiting thereof.

The present disclosure provides an array substrate, a method of manufacturing the same, and a display panel.

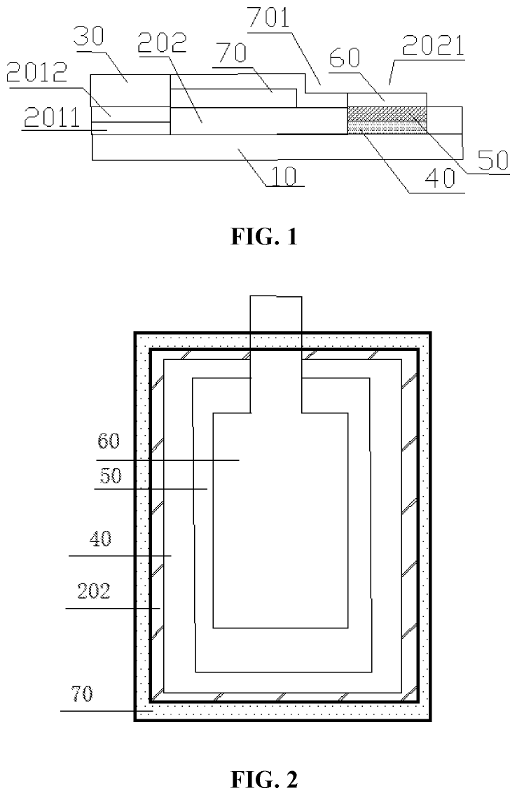

Referring to FIG. 1, FIG. 1 is a schematic cross-sectional view of a structure of an array substrate according to an embodiment of the present disclosure. One embodiment of the disclosure provides an array substrate including a base 10. The base is provided with a display region and a non-display region. A thin film transistor layer 20 and a first pixel electrode layer 30 are disposed in sequence on the base. The thin film transistor layer 20 includes a thin film transistor 201 disposed in the display region and an interlayer dielectric layer 202 disposed in the non-display region. The thin film transistor 201 further includes a second gate layer 2011 and a second source/drain layer 2012 disposed in the display region. The second gate layer and the second source/drain layer are connected by a via hole. The thin film transistor 201 further includes some other structures such as an interlayer dielectric layer, a poly-silicon layer, and an insulating layer not shown in the figure. The interlayer dielectric layer 202 is provided with a first via hole 2021 corresponding to the non-display region of the base. A detecting device disposed in the non-display region of the base. The detecting device includes:

a first gate metallic layer 40 deposited on the base 10 corresponding to the first via hole 2021;

a first source/drain layer 50 deposited on the first gate metallic layer 40, wherein the first source/drain layer 50 is disposed in the first via hole 2021; and

a second pixel electrode layer 60 deposited on the first source/drain layer 50, wherein the second pixel electrode layer 60 is connected to the first pixel electrode layer 30 by a trace.

The array substrate of the disclosure provides the interlayer dielectric layer 202 with a first via hole 2021 and deposits the first source/drain layer 50 totally within the first via hole 2021 to reduce a height difference between the first source/drain layer 50 and the interlayer dielectric layer 202 of the array substrate to prevent from breaking of trace between an interface of the first source/drain layer 50 and the interlayer dielectric layer 202 to promote a reliability of the detecting device.

In one embodiment of the disclosure, the array substrate further includes a planarization layer 70. The planarization layer 70 is an organic planarization layer. The organic planarization layer 70 is provided on the interlayer dielectric layer 202. The organic planarization layer 70 is disposed between the thin film transistor layer 20 and the first pixel electrode layer 30. The organic planarization layer is configured to provide a plane surface of a upper surface of a display panel and to prevent from affection of display by a rough surface. The organic planarization layer 70 is provided with a second via hole 701 in the non-display region of the base 10 to define a testing region for easily testing the display panel later. The first via hole 2021 is also disposed in the testing region. The second via hole is provided with other structures of the array substrate. The detail of the other structures may refer to prior art, and are not limited here.

Base on the above embodiment, the second pixel electrode layer is deposited on the organic planarization layer 70. The trace is deposited on the testing region defined by the second via hole 701. The second pixel electrode layer 60 is also deposited on the first source/drain layer 50. The trace is configured to connect the display panel with the testing region for detecting later by connecting the second pixel electrode layer in the display region with the first pixel electrode layer in the non-displayer region.

In one embodiment of the array substrate of the disclosure, an area of the first via hole 2021 is greater than an area of the first gate metallic layer 40. In other embodiment of the array substrate of the disclosure, an area of the first via hole 2021 is equal to an area of the first gate metallic layer 40.

When an area of the first via hole 2021 is greater than an area of the first gate metallic layer 40, and the first source/drain layer 50 is totally deposited within the first via hole 2021. An area of the first source/drain layer 50 is greater than the area of the first gate metallic layer 40. A height of an upper surface of the first source/drain layer 50 is equal to a height of an upper surface of the interlayer dielectric layer 202. The height of the upper surface of the first source/drain layer 50 and the height of the upper surface of the interlayer dielectric layer 202 is at the same level.

Referring to FIG. 2, FIG. 2 is a schematic top view of a structure of an array substrate according to another embodiment of the present disclosure. The planarization layer 70 is disposed at the most outward of the array substrate. The interlayer dielectric layer 202 is disposed on the planarization layer 70. The interlayer dielectric layer 202 is less than the planarization layer 70. The first gate metallic layer 40 is disposed in the interlayer dielectric layer 202. The first source/drain layer 50 is deposited on the first gate metallic layer 40. The first gate metallic layer 40 and the first source/drain layer 50 are rectangular. The second pixel electrode layer 60 is deposited on the first source/drain layer 50. The first pixel electrode layer 30 is deposited on the interlayer dielectric layer 202. The first pixel electrode layer 30 and the second pixel electrode layer 60 is connected by the trace. The display region and the non-display region of the display panel is connected by the trace.

In some embodiments of the present invention, a material of the gate layer may be a metal material such as molybdenum. A material of the source/drain electrode may be an aluminum alloy, and in detail, may be a Ti—Al—Ti alloy.

It should be noted that, in the above-mentioned embodiment of the array substrate, only the above structure is described. It can be understood that, in addition to the above structure, the display panel of the embodiment of the present invention may further include any other necessary structure as needed, the detail is not limited here.

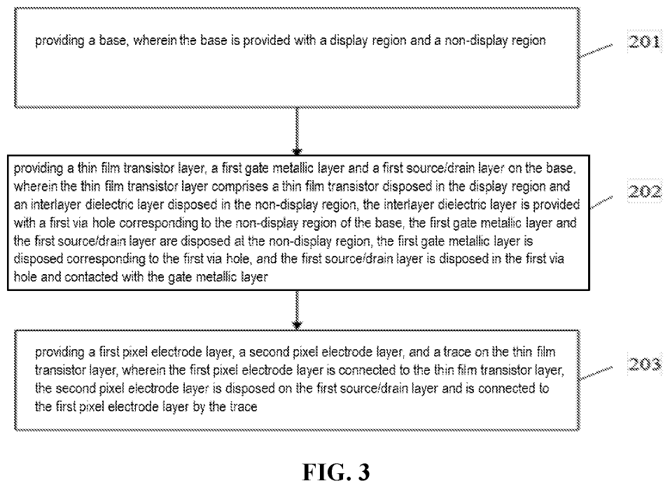

Furthermore, another embodiment of the disclosure provides a method of manufacturing an array substrate. The array substrate includes a display region and a non-display region. Referring to FIG. 3, FIG. 3 is a schematic flowchart of a method of manufacturing an array substrate according to an embodiment of the present disclosure. The method includes steps from 201 to 203, and is describing as following:

Step 201: providing a base, wherein the base is provided with a display region and a non-display region;

Step 202: providing a thin film transistor layer, a first gate metallic layer and a first source/drain layer on the base, wherein the thin film transistor layer includes a thin film transistor disposed in the display region and an interlayer dielectric layer disposed in the non-display region, the interlayer dielectric layer is provided with a first via hole corresponding to the non-display region of the base, the first gate metallic layer and the first source/drain layer are disposed at the non-display region, the first gate metallic layer is disposed corresponding to the first via hole, and the first source/drain layer is disposed in the first via hole and contacted with the gate metallic layer; and

Step 203: providing a first pixel electrode layer, a second pixel electrode layer, and a trace on the thin film transistor layer, wherein the first pixel electrode layer is connected to the thin film transistor layer, the second pixel electrode layer is disposed on the first source/drain layer and is connected to the first pixel electrode layer by the trace.

The method of manufacturing an array substrate of the disclosure provides the interlayer dielectric layer with a via hole and deposits the source/drain layer totally within the first via hole to reduce a height difference between the source/drain layer and the interlayer dielectric layer of the array substrate to prevent from breaking of trace between an interface of the source/drain layer and the interlayer dielectric layer to promote a reliability of the detecting device.

In detail, providing the thin film transistor layer and the first pixel electrode layer in sequence after providing the base. The thin film transistor layer includes a thin film transistor disposed in the display region and an interlayer dielectric layer disposed in the non-display region. Meanwhile, providing the interlayer dielectric layer with a first via hole corresponding to the non-display region of the base.

In one embodiment of the method of manufacturing the array substrate of the disclosure, the step 202 of providing a thin film transistor layer, a first gate metallic layer and a first source/drain layer on the base further includes steps of:

1. providing a first gate layer and a second gate layer on the base;

2. providing a first source/drain layer on the first gate layer; and

3. providing the thin film transistor on the second gate layer.

In detail, coating a layer of gate material on a region on the non-display region of the base corresponding to the first via hole and on the display region of a display panel; providing a patterned mask layer on the gate material layer; and shrinking the patterned mask layer by wet etching, and removing part of the gate material layer under a covering of the patterned mask layer to form a first gate metallic layer and a second gate metallic layer respectively. Providing the first source/drain layer on the first gate metallic layer and providing the second source/drain layer on the second gate metallic layer after providing the first gate metallic layer and the second gate metallic layer.

The detail method of preparing structures of the display panel such as the thin film transistor may refer to prior art, and is not limited here.

A height of an upper surface of the first gate metallic layer is less than a height of the interlayer dielectric layer. The first source/drain layer is deposited on the first gate metallic layer and a height of an upper surface of the first source/drain layer is equal to a height of an upper surface of the interlayer dielectric layer. The upper surface of the first source/drain layer and the upper surface of the interlayer dielectric layer is at the same level. The first source/drain layer is totally deposited within the first via hole and is corresponding to the first gate metallic layer. Because the height of the upper surface of the first source/drain layer is equal to the height of the upper surface of the interlayer dielectric layer, there has no height difference between the upper surface of the first source/drain layer and the upper surface of the interlayer dielectric layer. An area of the first source/drain layer is greater than or equal to an area of the first gate metallic layer.

In one embodiment of the disclosure, the method of manufacturing the array substrate further includes steps before the step 203 of providing the first pixel electrode layer, the second pixel electrode layer, and the trace on the thin film transistor layer, wherein the steps include:

providing an organic planarization layer on the thin film transistor layer; and providing a second via hole on the organic planarization layer corresponding to the non-display region to define a testing region, wherein the first via hole is disposed in the testing region, the first pixel electrode layer is disposed on the organic planarization layer, the second pixel electrode layer is disposed on the source/drain layer, and the trace is disposed on the organic planarization layer and the interlayer dielectric layer.

In detail, providing an organic planarization layer on the thin film transistor layer; and providing a second via hole on the organic planarization layer corresponding to the non-display region to define a testing region for later test. The first via hole is disposed in the testing region. the first pixel electrode layer is disposed on the organic planarization layer after the step of providing the organic planarization layer. Providing the second pixel electrode layer on the source/drain layer. The trace can prepare at the same time of preparing the pixel electrode or prepare after the preparing of the pixel electrode. The trace is connected the first pixel electrode layer with the second pixel electrode layer. A material of the trace includes indium gallium zinc material. The trace has no height difference at the interface between the display region and the non-display region of the display panel. The trace will not be broken so that prevent from failure of detecting device caused by trace breaking.

Number of the detecting device of the array substrate in the embodiment of the invention may be plural. The detecting device is connected to the array substrate for detecting defects in the array substrate.

Furthermore, another embodiment of the disclosure provides a display panel, including the abovementioned array substrate. The array substrate includes a base 10. The base is provided with a display region and a non-display region. A thin film transistor layer 20 and a first pixel electrode layer 30 are disposed in sequence on the base. The thin film transistor layer 20 includes a thin film transistor 201 disposed in the display region and an interlayer dielectric layer 202 disposed in the non-display region. The first pixel electrode layer 30 is connected to the thin film transistor layer 20. The interlayer dielectric layer 202 is provided with a first via hole 2021 corresponding to the non-display region of the base. A detecting device is disposed in the non-display region of the base. The detecting device includes:

a first gate metallic layer 40 deposited on the base 10 corresponding to the first via hole 2021;

a first source/drain layer 50 deposited on the first gate metallic layer 40, wherein the first source/drain layer 50 is disposed in the first via hole 2021; and

a second pixel electrode layer 60 deposited on the first source/drain layer 50, wherein the second pixel electrode layer 60 is connected to the first pixel electrode layer 30 by a trace.

The display panel of the disclosure provides the interlayer dielectric layer of the array substrate with a via hole and deposits the source/drain layer totally within the first via hole to reduce a height difference between the source/drain layer and the interlayer dielectric layer of the array substrate to prevent from breaking of trace between an interface of the source/drain layer and the interlayer dielectric layer to promote a reliability of the detecting device.

The present disclosure of an array substrate, a method of manufacturing the same and a display panel has been described by the above embodiments, but the embodiments are merely examples for implementing the present disclosure. It must be noted that the embodiments do not limit the scope of the invention. In contrast, modifications and equivalent arrangements are intended to be included within the scope of the invention.

What is claimed is:

1. An array substrate, comprising:
a base, wherein the base is provided with a display region and a non-display region;
a thin film transistor layer and a first pixel electrode layer disposed in sequence on the base, wherein the thin film transistor layer comprises a thin film transistor disposed in the display region and an interlayer dielectric layer disposed in the non-display region, the first pixel electrode layer is connected to the thin film transistor layer, and the interlayer dielectric layer is provided with a first via hole corresponding to the non-display region of the base; and
a detecting device disposed in the non-display region of the base, wherein the detecting device comprises:
a first gate metallic layer deposited on the base corresponding to the first via hole;
a first source/drain layer deposited on the first gate metallic layer, wherein the first source/drain layer is disposed in the first via hole; and
a second pixel electrode layer deposited on the first source/drain layer, wherein the second pixel electrode layer is connected to the first pixel electrode layer by a trace.

2. The array substrate according to claim 1, further comprising a planarization layer disposed between the thin film transistor layer and the first pixel electrode layer, wherein the planarization layer is provided with a second via hole in the non-display region of the base to define a testing region, and the first via hole is disposed in the testing region.

3. The array substrate according to claim 2, wherein the trace is deposited on the planarization layer and the interlayer dielectric layer.

4. The array substrate according to claim 1, wherein an area of the first via hole is greater than or equal to an area of the first gate metallic layer.

5. The array substrate to claim 4, wherein an area of the first via hole is greater than an area of the first gate metallic layer, and the first source/drain layer is totally deposited within the first via hole.

6. The array substrate to claim 1, wherein a height of an upper surface of the first gate metallic layer is less than a height of the interlayer dielectric layer.

7. The array substrate to claim 6, wherein a height of an upper surface of the first source/drain layer is equal to a height of an upper surface of the interlayer dielectric layer.

8. A method of manufacturing an array substrate, comprising steps of:
providing a base, wherein the base is provided with a display region and a non-display region;
providing a thin film transistor layer, a first gate metallic layer and a first source/drain layer on the base, wherein the thin film transistor layer comprises a thin film transistor disposed in the display region and an interlayer dielectric layer disposed in the non-display region, the interlayer dielectric layer is provided with a first via hole corresponding to the non-display region of the base, the first gate metallic layer and the first source/drain layer are disposed at the non-display region, the first gate metallic layer is disposed corresponding to the first via hole, and the first source/drain layer is disposed in the first via hole and contacted with the gate metallic layer; and
providing a first pixel electrode layer, a second pixel electrode layer, and a trace on the thin film transistor layer, wherein the first pixel electrode layer is connected to the thin film transistor layer, the second pixel electrode layer is disposed on the first source/drain layer and is connected to the first pixel electrode layer by the trace.

9. The method of manufacturing the array substrate according to claim 8, further comprising steps before the step of providing the first pixel electrode layer, the second pixel electrode layer, and the trace on the thin film transistor layer, wherein the steps comprise:
providing a planarization layer on the thin film transistor layer; and
providing a second via hole on the planarization layer corresponding to the non-display region to define a testing region, wherein the first via hole is disposed in the testing region, the first pixel electrode layer is disposed on the planarization layer, the second pixel electrode layer is disposed on the first source/drain layer, and the trace is disposed on the planarization layer and the interlayer dielectric layer.

10. The method of manufacturing the array substrate according to claim 9, wherein a material of the trace comprises indium gallium zinc material.

11. The method of manufacturing the array substrate according to claim 8, wherein the step of providing a thin film transistor layer, a first gate metallic layer and a first source/drain layer on the base further comprises steps of:
providing a first gate layer and a second gate layer on the base;
providing a first source/drain layer on the first gate layer; and
providing the thin film transistor on the second gate layer.

12. The method of manufacturing the array substrate according to claim 11, wherein the step of providing the first gate layer and the second gate layer on the base comprises steps of:
coating a layer of gate material on a region on the non-display region of the base corresponding to the first via hole and on the display region of a display panel;
providing a patterned mask layer on the gate material layer; and
shrinking the patterned mask layer by wet etching, and removing part of the gate material layer under a covering of the patterned mask layer to form a first gate metallic layer and a second gate metallic layer respectively.

13. The method of manufacturing the array substrate according to claim 8, wherein a height of an upper surface of the first gate metallic layer is less than a height of the interlayer dielectric layer.

14. The method of manufacturing the array substrate according to claim 13, wherein a height of an upper surface of the first source/drain layer is equal to a height of an upper surface of the interlayer dielectric layer

15. A display panel, comprising an array substrate, wherein the array substrate comprises:
a base, wherein the base is provided with a display region and a non-display region;
a thin film transistor layer and a first pixel electrode layer disposed in sequence on the base, wherein the thin film transistor layer comprises a thin film transistor disposed in the display region and an interlayer dielectric layer disposed in the non-display region, the first pixel electrode layer is connected to the thin film transistor layer, and the interlayer dielectric layer is provided with a first via hole corresponding to the non-display region of the base; and
a detecting device disposed in the non-display region of the base, wherein the detecting device comprises:
a first gate metallic layer deposited on the base corresponding to the first via hole;
a first source/drain layer deposited on the first gate metallic layer, wherein the first source/drain layer is disposed in the first via hole; and
a second pixel electrode layer deposited on the first source/drain layer, wherein the second pixel electrode layer is connected to the first pixel electrode layer by a trace.

16. The display panel according to claim 15, wherein the array substrate further comprises a planarization layer disposed between the thin film transistor layer and the first pixel electrode layer, wherein the planarization layer is provided with a second via hole in the non-display region of the base to define a testing region, and the first via hole is disposed in the testing region.

17. The display panel according to claim 16, wherein the trace is deposited on the planarization layer and the interlayer dielectric layer.

18. The display panel according to claim 15, wherein an area of the first via hole is greater than or equal to an area of the first gate metallic layer.

19. The display panel according to claim 15, wherein a height of an upper surface of the first gate metallic layer is less than a height of the interlayer dielectric layer.

20. The display panel according to claim 19, wherein a height of an upper surface of the first source/drain layer is equal to a height of an upper surface of the interlayer dielectric layer.
